(19) United States
(12) Patent Application Publication
(10) Pub. No.: US 2005/0184328 A1
(43) Pub. Date: Aug. 25, 2005

(54) Semiconductor device and its manufacturing method

(75) Inventors: Kiyoshi Uchiyama, Osaka (JP); Shintarou Ida, Osaka (JP); Yasuhiro Shimada, Kyoto (JP); Kazunori Isogai, Kyoto (JP); Yoshihisa Kato, Shiga (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/059,451

(22) Filed: Feb. 17, 2005

(30) Foreign Application Priority Data
Feb. 19, 2004 (JP) 2004-043145
Sep. 28, 2004 (JP) 2004-281395

(51) Int. Cl. H01L 27/108

(52) U.S. Cl. 257/306

(57) ABSTRACT

In a semiconductor device in which a thin film containing a metal oxide is formed on a semiconductor element, the thin film is an aggregate of crystal particles formed of the metal oxide, and the crystal particles are bonded to each other at a part of its surface.

### CROSS-REFERENCE TO RELATED APPLICATION

Terms disclosed in specifications, drawings and claims in Japanese Patent Application No. 2004-043145 filed on Feb. 19, 2004 and Japanese Patent Application No. 2004-2813955 filed on Sep. 28, 2004 are incorporated herein by reference.

### BACKGROUND OF THE INVENTION

The present invention relates to a semiconductor device in which a thin film containing a metal oxide is formed on a semiconductor substrate and its manufacturing method.

Conventionally, when a semiconductor device integrating a capacitor element formed of a capacitor insulating film formed of a metal oxide which is a high dielectric material or a ferroelectric material with another circuit element is formed, the capacitor insulating film is formed as a metal oxide thin film having a constant composition in general.

FIG. 11 is a sectional view showing an essential part of a semiconductor device which integrates a capacitor element formed of a capacitor insulating film formed of a metal oxide which is a high dielectric material or a ferroelectric material with a memory cell transistor. In addition, other circuit elements (not shown) are formed on a semiconductor substrate 501.

As shown in FIG. 11, an impurity diffusion region 502a is formed on the semiconductor substrate 501. In addition, a gate insulation film 502b and a gate electrode 502c are sequentially formed on the semiconductor substrate 501, and a side wall 502d is formed on each side face of the gate insulation film 502b and the gate electrode 502c. Thus, a memory cell transistor 502 composed of the impurity diffusion region 502a, the gate insulation film 502b, the gate electrode 502c and the side wall 502d is formed. In addition, an insulation film 503 is formed on the semiconductor substrate 501 so as to cover the memory cell transistor 502, and a contact plug 504 whose lower end is connected to the impurity diffusion region 502a is formed in the insulation film 503. In addition, a lower electrode 505 which is electrically connected to the contact plug 504 is formed on the insulation film 503. A capacitor insulating film 506 containing a metal oxide which is a high dielectric material or a ferroelectric material and an upper electrode 507 are sequentially formed on the lower electrode 505. Thus, a capacitor element 508 composed of the lower electrode 505, the capacitor insulating film 506 and the upper electrode 507 is formed.

Here, as a method of forming the metal oxide thin film serving as the capacitor insulating film 506 shown in FIG. 11, a spin-on method in which a metal organic material is applied on the lower electrode 505 which constitutes the capacitor element 508, a chemical vapor deposition method (referred to as the CVD method hereinafter) and a sputtering method have been used.

According to the spin-on method, it is necessary to perform a heat treatment in an oxygen atmosphere (referred to as the crystallization annealing hereinafter) at a high temperature in order to oxidize the applied metal organic material. In addition, according to the CVD method or the sputtering method, since a formed thin film is an amorphous metal oxide thin film in many cases, in order to realize a high dielectric constant and ferroelectric property, it is necessary to perform a heat treatment in an oxygen atmosphere at a high temperature in general similar to the spin-on method. For example, in Japanese Unexamined Patent Publication No. 9-69614, the spin-on method is proposed in a conventional manner and in Japanese Unexamined Patent Publication No. 2003-174028, the CVD method is proposed in a conventional manner.

FIG. 12 is a flowchart showing a general manufacturing method of the capacitor element 508 having the capacitor insulating film 506 formed of the metal oxide thin film formed on the lower electrode by the spin-on method.

First, the lower electrode 505 is formed on the semiconductor substrate 501 at step S601 shown in FIG. 12 (a lower electrode forming step).

Then, a raw material solution is applied to form the metal oxide thin film on the lower electrode 505 at step S602 shown in FIG. 12 (a spin-on step).

Then, a solvent in the raw material solution applied on the lower electrode 505 is evaporated at a baking temperature of 200 to 300° C. at step S603 shown in FIG. 12 (a soft baking step). Thus, a precursor thin film which will be the metal oxide film is formed.

Then, the capacitor insulating film 506 formed of the metal oxide thin film is formed by crystallizing the precursor thin film at step S604 shown in FIG. 12 (a crystallization annealing step). An annealing temperature at this time is 700 to 800° C. which is a relatively high temperature for an integration process of a semiconductor.

Then, the upper electrode 507 is formed on the capacitor insulating film 506 formed of the metal oxide thin film at step S605 shown in FIG. 12 (an upper electrode forming step).

Then, a configuration of the capacitor element 508 having the capacitor insulating film 506 formed of the metal oxide thin film is processed by patterning and etching at step S606 shown in FIG. 12 (a capacitor element processing step).

Then, a crystal property of the metal oxide thin film damaged at the step S606 is restored at step S607 shown in FIG. 12.

Thus, the capacitor element 508 is formed on the semiconductor substrate 501 by the spin-on method.

FIG. 13 is a flowchart showing a general manufacturing method of the capacitor element 508 having the capacitor insulating film 506 formed of the metal oxide thin film formed on the lower electrode by the CVD method.

First, the lower electrode 505 is formed on the semiconductor substrate 501 at step S701 shown in FIG. 13 (a lower electrode forming step).

Then, the metal oxide thin film is formed on the lower electrode 505 by the CVD method at step S702 shown in FIG. 13 (a CVD step).

Then, since the formed metal oxide thin film is in an amorphous state in general, the capacitor insulating film 506 formed of the metal oxide thin film is formed by crystallizing the metal oxide thin film at step S703 shown in FIG. 13 (a crystallization annealing step). An annealing temperature at this time is 600 to 800° C. which is a relatively high temperature for the integration process of the semiconductor.

Then, the upper electrode 507 is formed on the capacitor insulating film 506 formed of the metal oxide thin film at step S704 shown in FIG. 13 (an upper electrode forming step).

Then, a configuration of the capacitor element 508 having the capacitor insulating film 506 formed of the metal oxide thin film is processed by patterning and etching at step S705 shown in FIG. 13 (a capacitor element processing step).

Then, a crystal property of the metal oxide thin film damaged at the step S705 is restored at step S706 shown in FIG. 13.

Thus, the capacitor element 508 is formed on the semiconductor substrate 501 by the CVD method.

Meanwhile, according to Japanese Unexamined Patent Publication No. 2001-53071, there is proposed a method of forming the metal oxide thin film by crystallizing a whole precursor, by performing a heat treatment for the precursor in which particles of a metal oxide are diffused in another metal oxide.

In addition, the above manufacturing method of the metal oxide is for manufacturing the thin film, and as another manufacturing method of the oxide, there is proposed a method of manufacturing oxide particles by using a laser ablation method as shown in Japanese Unexamined Patent Publication No. 2003-137553.

### SUMMARY OF THE INVENTION

Meanwhile, according to the conventional method of forming the metal oxide thin film disclosed in the Japanese Unexamined Patent Publication No. 9-69614 and the Japanese Unexamined Patent Publication No. 2003-174028, it is necessary to perform annealing at 600° C. or more normally at the crystallization annealing step (the step S604 or S703) in order to provide the metal oxide thin film of the high dielectric material or the ferroelectric material which is superior in electric characteristics and crystal property. Therefore, heat damage could be applied to the memory cell transistor 503 or another circuit element formed on the semiconductor substrate 501 at the crystallization annealing step (at the step S604 or S703).

Especially, when a metal oxide thin film formed of SrBi₂Ta₂O₃ (referred to as the SBT hereinafter) which is a typical ferroelectric material used in a ferroelectric random access memory (referred to as the FeRAM hereinafter) is provided, it is necessary to perform annealing at 650° C. or more in general at the crystallization annealing step (at the step S604 or S703). Thus, the point which the high-temperature annealing is necessary is restriction on a process when the FeRAM is manufactured.

In addition, according to the conventional method of forming the metal oxide thin film disclosed in the Japanese Unexamined Patent Publication No. 2001-53071, since the whole precursor in which the metal oxide particles are diffused in another metal oxide material is crystallized by the heat treatment, the heat treatment temperature is high like the manufacturing method disclosed in the Japanese Unexamined Patent Publication No. 9-69614 or the Japanese Unexamined Patent Publication No. 2003-174028.

As described above, the heat damage caused by the heat treatment at the high temperature in the crystallization annealing is a serious problem when the capacitor element comprising the capacitor insulating film formed of the metal oxide which is the high dielectric material or the ferroelectric material and another circuit element are integrated. Among of all, it is a very serious problem in a super high integrating process of 0.13 μm rule or less.

In view of the above problems, it is an object of the present invention to provide a semiconductor device which can be formed at a low temperature so that heat damage is not applied to a semiconductor element when the semiconductor device comprising a thin film formed of a metal oxide is formed on the semiconductor element, and its manufacturing method.

In order to attain the above object, a first semiconductor device according to the present invention is a semiconductor device in which a thin film containing a metal oxide is formed on a semiconductor element, and it is characterized in that the thin film is an aggregate of crystal particles formed of the metal oxide, and the crystal particles are bonded to each other at a part of its surface.

According to the first semiconductor device of the present invention, since the thin film is the aggregate of the crystal particles formed of the metal oxide, it is not always necessary to perform the crystallization annealing for the thin film and even when the crystallization annealing is performed, it may be performed at a low temperature. Therefore, the semiconductor device comprising the thin film formed of the metal oxide can be formed on the circuit element at the low temperature so that the circuit element such as the memory cell transistor may not be damaged by the heat. Thus, as compared with the conventional example, the heat damage applied to the semiconductor element can be considerably reduced.

A second semiconductor device according to the present invention is a semiconductor device in which a thin film containing a metal oxide is formed on a semiconductor element, and it is characterized in that the thin film comprises crystal particles formed of the metal oxide diffused in a medium material.

According to the second semiconductor device of the present invention, since the thin film comprises the crystal particles formed of the metal oxide diffused in the medium material so that it comprises the crystal particles and the medium material, it is not always necessary to crystallize the medium material. Therefore, it is not always necessary to perform the crystallization annealing for the thin film in which the crystal particles formed of the metal oxide are diffused in the medium material. Even when the crystallization annealing is performed, it may be performed at a low temperature. Therefore, when the crystal particles formed of the metal oxide are previously prepared, the semiconductor device comprising the thin film formed of the metal oxide can be formed on a circuit element at the low temperature so that the circuit element such as the memory cell transistor may not be damaged by the heat. Thus, as compared with the conventional example, the heat damage applied to the semiconductor element can be considerably reduced.

A third semiconductor device of the present invention is a semiconductor device in which a thin film containing a metal oxide is formed on a semiconductor element, and it is characterized in that the thin film comprises crystal particles formed of the metal oxide and bonded by a bonding material.

According to the third semiconductor device of the present invention, since the crystal particles formed of the metal oxide are bonded by the bonding material in the thin film, it is not always necessary that the bonding material has been crystallized. Therefore, it is not always necessary to perform the crystallization annealing for the thin film in which the crystal particles formed of the metal oxide are bonded to each other by the bonding material. Even when the crystallization annealing is performed, it may be performed at a low temperature. Therefore, when the crystal particles formed of the metal oxide are previously prepared, the semiconductor device comprising the thin film formed of the metal oxide can be formed on a circuit element at the low temperature so that the circuit element such as the memory cell transistor may not be damaged by the heat. Thus, as compared with the conventional example, the heat damage applied to the semiconductor element can be considerably reduced. In addition, an amount of the bonding material is provided only to bond the crystal particles formed of the metal oxides, its ratio in the thin film containing the metal oxide can be extremely small. Therefore, the thin film containing the metal oxide can have a property which is extremely close to the property such as the high dielectric property or the ferroelectric property of the high dielectric thin film or the ferroelectric thin film containing only the metal oxide constituting the crystal particles, for example.

It is preferable in the second or the third semiconductor device according to the present invention that the medium material or the bonding material is an amorphous material.

Thus, since the amorphous material can be formed at a relatively low temperature, there can be provided the thin film containing the metal oxide which can be formed at the relatively low temperature.

It is preferable in the second or the third semiconductor device according to the present invention that the medium material or the bonding material is formed of an organic material.

Thus, since it is not necessary to perform the heat treatment for oxidization for the medium material formed of the organic material, there can be provided the thin film containing the metal oxide which can be formed at the relatively low temperature.

It is preferable in the second or the third semiconductor device according to the present invention that the medium material or the bonding material has a relative dielectric constant higher than that of a silicon oxide.

Thus, there can be provided the thin film containing the metal oxide having the high relative dielectric constant.

It is preferable in the first to the third semiconductor devices according to the present invention that an average particle diameter of the crystal particle is smaller than a minimum line width of the semiconductor element.

Thus, possibility of a short circuit can be considerably reduced even when the crystal particles formed of metal oxide are dispersed and attached on the integrated circuit element.

It is preferable in the first to the third semiconductor devices according to the present invention that the thin film comprises a ferroelectric thin film or a high dielectric thin film.

In this case, since the thin film containing the metal oxide has the plurality of crystal particles, the required high dielectric property or ferroelectric property can be provided without crystallization annealing at the high temperature.

A method of manufacturing the first semiconductor device comprises a step of depositing crystal particles formed of a metal oxide on a substrate, and a step of forming a thin film formed of the bonded crystal particles on the substrate, by performing a heat treatment for the substrate.

According to the method of manufacturing the first semiconductor device of the present invention, when the thin film formed of the bonded crystal particles is formed on the substrate, the heat treatment temperature can be lowered. Therefore, there can be formed the semiconductor device in which the thin film containing the metal oxide is formed, on the circuit element at the low temperature so that the heat damage is not applied to the circuit element such as the memory cell transistor. Thus, as compared with the conventional example, the heat damage applied to the semiconductor element can be considerably reduced.

A method of manufacturing the second semiconductor device comprises a step of diffusing crystal particles formed of a metal oxide, in a raw material solution containing a medium material, a step of applying the raw material solution containing the diffused crystal particles, onto a substrate, and a step of forming a thin film formed of the diffused crystal particles in the medium material, on the substrate by performing a heat treatment for the substrate.

According to the method of manufacturing the second semiconductor device of the present invention, when the thin film formed of the diffused crystal particles in the medium material is formed on the substrate, the heat treatment temperature can be lowered. Therefore, there can be formed the semiconductor device in which the thin film containing the metal oxide is formed, on the circuit element at the low temperature so that the heat damage is not applied to the circuit element such as the memory cell transistor. Thus, as compared with the conventional example, the heat damage applied to the semiconductor element can be considerably reduced. In addition, in this case, the thin film formed of the diffused crystal particles in the medium material can be easily formed by the normal spin-on method.

A method of manufacturing a third semiconductor device comprises a step of diffusing crystal particles formed of a metal oxide, in raw material gas used in a chemical vapor deposition method or raw material gas carrying gas, and a step of forming a thin film formed of the diffused crystal particles in the medium material, on the substrate using the raw material gas or raw material gas carrying gas in which the crystal particles are diffused, by a chemical vapor deposition method.

According to the method of manufacturing the third semiconductor device of the present invention, when the thin film formed of the diffused crystal particles in the medium material is formed on the substrate, the heat treatment temperature can be lowered. Therefore, there can be formed the semiconductor device in which the thin film containing the metal oxide is formed by the CVD method, on the circuit element at the low temperature so that the heat damage is not applied to the circuit element such as the memory cell transistor. Thus, as compared with the conventional example, the heat damage applied to the semiconductor element can be considerably reduced.

A method of manufacturing the fourth semiconductor device comprises a step of diffusing crystal particles formed of a metal oxide, in a raw material solution containing a bonding material, a step of applying the raw material solution containing the diffused crystal particles, onto a substrate, an a step of forming a thin film formed of the crystal particles bonded by the bonding material, on the substrate by performing a heat treatment for the substrate.

According to the method of manufacturing the fourth semiconductor device of the present invention, when the thin film formed of the crystal particles bonded by the bonding material is formed on the substrate, the heat treatment temperature can be lowered. Therefore, there can be formed the semiconductor device in which the thin film containing the metal oxide is formed, on the circuit element at the low temperature so that the heat damage is not applied to the circuit element such as the memory cell transistor. Thus, as compared with the conventional example, the heat damage applied to the semiconductor element can be considerably reduced.

A method of manufacturing the fifth semiconductor device comprises a step of manufacturing a mixture solution in which crystal particles formed of a metal oxide and particles formed of a medium material are mixed in a solvent, a step of applying the mixture solution onto a substrate, and a step of forming a thin film formed of the crystal particles diffused in the medium material, on the substrate by softening the crystal particles formed of the medium material, by performing a heat treatment for the substrate.

According to the method of manufacturing the fifth semiconductor device of the present invention, when the thin film formed of the crystal particles diffused in the medium material is formed on the substrate, the heat treatment temperature can be lowered. Therefore, there can be formed the semiconductor device in which the thin film containing the metal oxide is formed on the circuit element at the low temperature so that the heat damage is not applied to the circuit element such as the memory cell transistor. Thus, as compared with the conventional example, the heat damage applied to the semiconductor element can be considerably reduced.

A method of manufacturing the sixth semiconductor device comprises a step of forming a mixture solution in which crystal particles formed of a metal oxide and particles formed of a bonding material are mixed in a solvent, a step of applying the mixture solution onto a substrate, and a step of forming a thin film formed of the crystal particles bonded by the bonding material, on the substrate by softening the crystal particles formed of the bonding material, by performing a heat treatment for the substrate.

According to the method of manufacturing the sixth semiconductor device of the present invention, when the thin film formed of the crystal particles bonded by the bonding material is formed on the substrate, the heat treatment temperature can be lowered. Therefore, there can be formed the semiconductor device in which the thin film containing the metal oxide is formed, on the circuit element at the low temperature so that the heat damage is not applied to the circuit element such as the memory cell transistor. Thus, as compared with the conventional example, the heat damage applied to the semiconductor element can be considerably reduced.

As described above, according to the present invention, the semiconductor device comprising the thin film formed of the metal oxide can be formed on the circuit element such as the memory cell transistor at the low temperature so that the heat damage is not applied to the circuit element.

### BRIEF DESCRIPTION OF THE DRAWINGS

FIG. 1 is a sectional view showing an essential part of a structure of a semiconductor device according to an embodiment 1 of the present invention.

FIG. 2 is a flowchart showing a method of manufacturing the semiconductor device according to the embodiment 1 of the present invention.

FIG. 3 is a sectional view showing an essential part of a variation of the structure of the semiconductor device according to the embodiment 1 of the present invention.

FIG. 4 is a sectional view showing an essential part of a structure of a semiconductor device according to an embodiment 2 of the present invention.

FIG. 5 is a flowchart showing a method of manufacturing the semiconductor device according to the embodiment 2 of the present invention.

FIG. 6 is a sectional view showing an essential part of a variation of the structure of the semiconductor device according to the embodiment 2 of the present invention.

FIG. 7 is a sectional view showing an essential part of a structure of a semiconductor device according to an embodiment 3 of the present invention.

FIG. 8 is a flowchart showing a method of manufacturing the semiconductor device according to the embodiment 3 of the present invention.

FIG. 9 is a sectional view showing an essential part of a structure of a semiconductor device according to an embodiment 4 of the present invention.

FIG. 10 is a flowchart showing a method of manufacturing the semiconductor device according to the embodiment 4 of the present invention.

FIG. 11 is a sectional view showing an essential part of a structure of a semiconductor device according to a conventional example.

FIG. 12 is a flowchart showing a method of manufacturing semiconductor device using a spin-on method according to a conventional example.

FIG. 13 is a flowchart showing a method of manufacturing semiconductor device using a CVD method according to a conventional example.

### DESCRIPTION OF THE PREFERRED EMBODIMENTS

Each embodiment of the present invention will be described with reference to the drawings hereinafter.

In addition, although a description will be made of a case where thin film formed of a metal oxide (referred to as the metal oxide thin film hereinafter) of the present invention is applied to a capacitor insulating film of a ferroelectric capacitor (capacitor element) in each embodiment of the present invention, the metal oxide thin film according to the present invention may be used as a capacitor insulating film of a semiconductor memory device such as a MFS (Metal-Ferroelectric-Semiconductor) type of transistor, a MFIS (Metal-Ferroelectric-Insulator-Semiconductor) type of transistor, or a MFMIS (Metal-Ferroelectric-Metal-Insulator-Semiconductor) type of transistor other than the ferroelectric capacitor.

In addition, a description will be made of a case where the metal oxide thin film is formed of SBT (SrBi₂Ta₂O₉) in each embodiment of the present invention, the metal oxide thin film may be formed of PZT (Pb (Zr, Ti)O₃) or BLT ((Bi, La)₄Ti₃O₁₂). Furthermore, the present invention can be applied to a metal oxide thin film formed of a high dielectric material such as BST (Sr, Bi) TiO₃ or Ta₂O₅ other than the metal oxide thin film formed of the ferroelectric material such as SBT or PZT.

(Embodiment 1)

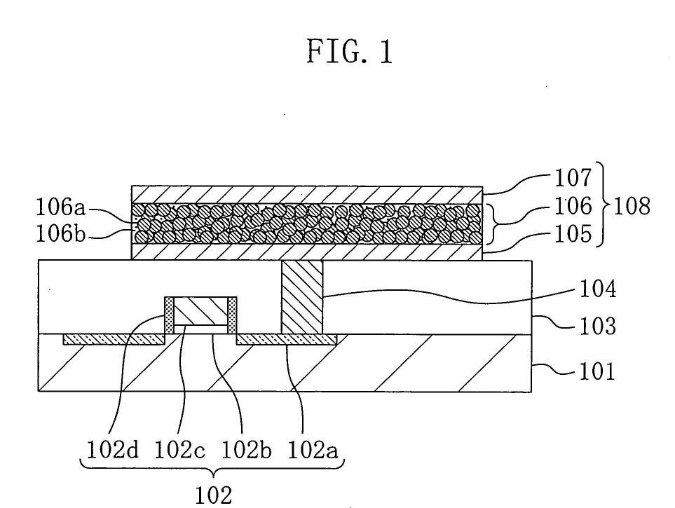

A semiconductor device according to an embodiment 1 of the present invention will be described with reference to FIG. 1.

FIG. 1 is a schematic view showing an essential part of the semiconductor device according to the embodiment 1 of the present invention. More specifically, the semiconductor device integrates a capacitor element comprising a capacitor insulating film formed of a metal oxide thin film and a memory cell transistor.

As shown in FIG. 1, an impurity diffusion region 102a is formed on a semiconductor substrate 101. In addition, a gate insulation film 102b and a gate electrode 102c are sequentially formed on the semiconductor substrate 101, and a side wall 102d is formed on each side face of the gate insulation film 102b and the gate electrode 102c. Thus, a memory cell transistor 102 comprising the impurity diffusion region 102a, the gate insulation film 102b, the gate electrode 102c and the side wall 102d is formed. In addition, an insulation film 103 is formed on the semiconductor substrate 101 so as to cover the memory cell transistor 102, and a contact plug 104 whose lower end is connected to the impurity diffusion region 102a is formed in the insulation film 103. In addition, a lower electrode 105 (its film thickness is about 200 nm) which comprises platinum and electrically connected to the contact plug 104 is formed on the insulation film 103. A metal oxide thin film 106 integrating oxide particles (crystal particles) 106a in a solvent 106b is formed on the lower electrode 105. Here, the oxide particle 106a is bonded to the adjacent oxide particle 106a at a part of its surface. An upper electrode 107 (its film thickness is about 200 nm) formed of platinum is formed on the metal oxide thin film 106. Thus, a capacitor element 108 comprises the lower electrode 105, the metal oxide thin film (capacitor insulating film) 106 and the upper electrode 107. In addition, integrated circuit elements (not shown) other than the memory cell transistor 102 may be further formed on the semiconductor substrate 101.

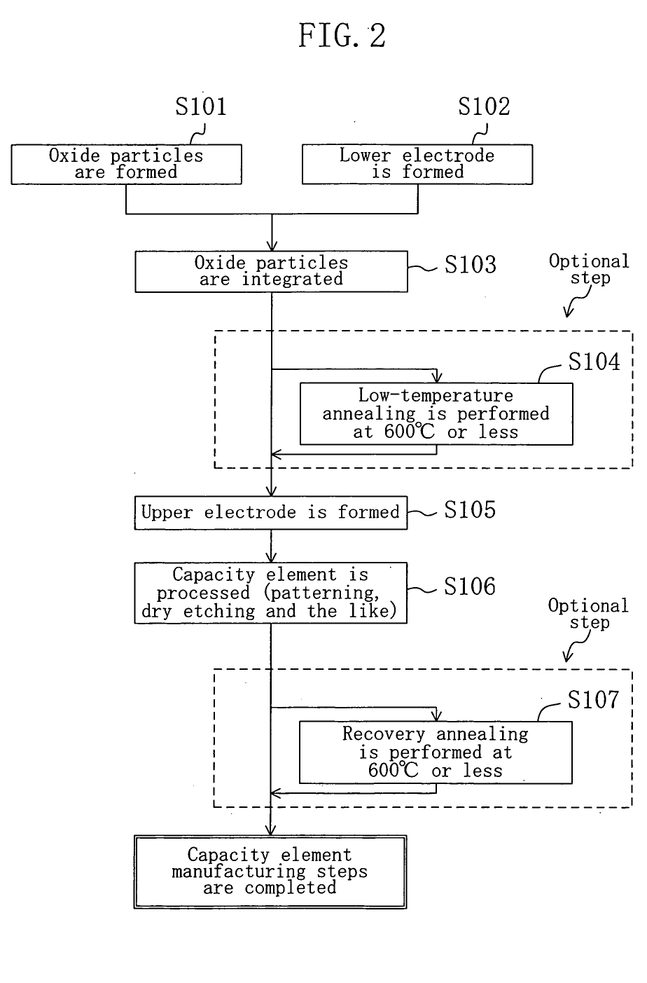

A method of manufacturing the semiconductor device according to the embodiment 1 of the present invention will be described with reference to FIG. 2 hereinafter. More specifically, a manufacturing method of the capacitor element 108 including a method of forming the metal oxide thin film 106 shown in FIG. 1 which is a characteristic part of the present invention will be described and other steps before the steps which will be described hereinafter are carried out by a normal method.

First, the oxide particles 106a formed of SBT which constitute the metal oxide thin film 106 shown in FIG. 1 is manufactured at step S101 shown in FIG. 2 (a step of manufacturing the oxide particles).

Here, the oxide particles 106a may be manufactured by any method. For example, a laser ablation method may be used. More specifically, a target oxide formed of SBT is irradiated with a laser and particles generated at that time are heated in a furnace. Then, the heated particles are collected to be the oxide particles 106a. As another manufacturing method, after double metal alcoxide of Sr—Ta and alcoxide of Bi are melted in ethanol, alcohol containing water is added in the solution while the solution is stirred, whereby the oxide particles 106a can be manufactured.

Meanwhile, the lower electrode 105 shown in FIG. 1 is formed at step S102 shown in FIG. 2 (a step of forming the lower electrode). More specifically, the lower electrode 105 whose lower face is electrically connected to an upper end of the contact plug 104 is formed on the insulation film 103 by the sputtering method. In addition, since the lower end of the contact plug 104 is connected to the impurity diffusion layer 102a, the transistor 102 is electrically connected to the lower electrode 105.

Here, it is desirable that a diameter of the oxide particle 106a is smaller than a minimum line width of the integrated circuit element comprising the transistor 203 or the contact plug 204 formed on the semiconductor substrate 101. Thus, possibility of a short circuit can be considerably reduced even when the oxide particles 106a formed of the metal oxide are attached on the integrated circuit element. Therefore, here, the oxide particle 106a is formed of SBT and its particle diameter is formed so as to be about 10 nm or less which is considerably small as compared with a minimum line width 130 nm of the integrated circuit element (in addition, a method of manufacturing the oxide particle having a fine diameter will be described in detail in an embodiment 3).

In addition, when particles in which glass particles containing boron oxide and silicon oxide as main components is mixed in the particles formed of SBT are used as the oxide particles 106a and heat is applied in a process after step S103 as will be described below (a step of integrating the oxide particles 106a), the integrated oxide particles 106a are strongly bonded to each other.

Then, the crystallized oxide particles 106a provided at the step S101 are integrated on the lower electrode 105 formed on the semiconductor substrate 101 at step S103 shown in FIG. 2 (a step of integrating the oxide particles). Thus, the metal oxide thin film 106 in which oxide particles 106a are integrated in the solvent 106b is formed.

Here, as a method of integrating the oxide particles 106a on the lower electrode 105, several methods can be used depending on the particle diameter or the surface state of the oxide particle 106a. According to this embodiment, the oxide particles 106a are diffused in the solvent 106b so as to become a sol. Then, the oxide particles 106a in the sol state are applied on the semiconductor substrate 101 by a method similar to the spin-on method and dried, whereby the metal oxide thin film 106 is formed. In this case, water is used as the solvent. The metal oxide thin film 106 formed of the oxide particles 106a which are not agglutinated to each other can be formed by adjusting a pH value of the water by acid or base.

Here, although the water is used to form the oxide particles 106a, the same effect can be provided when alcohol is used. In addition, gas may be used instead of liquid as the solvent. In this case, the metal oxide thin film 106 formed of the oxide particles 106a which are not agglutinated to each other can be formed also by spraying the oxide particles 106a which are made to be in an aerosol state, onto the semiconductor substrate 101.

In addition, after the step S103 in which the oxide particles 106a are integrated, step S104 (a low-temperature annealing step) shown in FIG. 2 may be optionally performed. That is, the oxide particles 106a are bonded to each other by performing the low-temperature annealing at the step S104, so that the strong metal oxide thin film 106 can be formed. At this time, as the lower electrode 105 or the upper electrode 107, when low melting point metal which can melt or become sufficiently soft at a temperature of the low-temperature annealing (which is lower than a melting point of aluminum in many cases) is used, the oxide particles 106a can be fused and bonded to the lower electrode 105 or the upper electrode 107. For example, when the oxide particles 106a are formed of a bismuth layered compound such as SBT or BLT, it is desirable to use low melting point metal containing bismuth (tin-indium-bismuth alloy, for example) as the lower electrode 105 or the upper electrode 107.

Then, the upper electrode 107 is formed on the metal oxide thin film 106 by the sputtering method at step S105 shown in FIG. 2 (a step of forming the upper electrode).

Then, a part other than a region in which the capacitor element 108 in the metal oxide thin film 106 or the upper electrode 107 is to be formed is removed by patterning, dry etching or the like, whereby the capacitor element 108 is formed at step S106 shown in FIG. 2 (a step of processing the capacitor element).

Step S107 (a recovery heat treatment step) shown in FIG. 2 may be performed after the step S106 optionally. That is, since the oxide particles 106a in the metal oxide thin film 106 are sufficiently crystallized, it is not damaged by the process at the step S106. Therefore, even if the recovery heat treatment at step 107 is not performed, there can be provided the capacitor element 108 having sufficient characteristics. Thus, the recovery heat treatment at the step S107 may be performed according to necessity. However, when this step is performed, process damage generated in the metal oxide thin film 106 at the step S106 can be removed by heating the semiconductor substrate 101 at 600° C. or less. The heat treatment temperature at this step S107 can be performed at a low temperature similar to the heat treatment temperature at the step S104.

Thus, the semiconductor device comprising the capacitor element 108 having the metal oxide thin film 106 can be formed on the semiconductor substrate 101.

As described above, according to the semiconductor device and its manufacturing method according to the embodiment 1 of the present invention, since the oxide particles 106a are crystallized at a sufficiently high temperature before they are integrated on the semiconductor substrate 101, the capacitor element 108 which is superior in high-dielectric or ferroelectric property can be easily provided without applying heat damage to the semiconductor substrate 101 or the integrated circuit elements such as the transistor 102 and the like formed thereon. In addition, according to the embodiment 1 of the present invention, when the oxide particles 106a are integrated, the oxide particles 106a can be integrated with a high orientation property on the lower electrode 105 by controlling the pH value of the sol oxide particles 106a. As a result, there can be provided a ferroelectric capacitor element which is formed of SBT and has 23 μC/cm² or more as residual polarization charges.

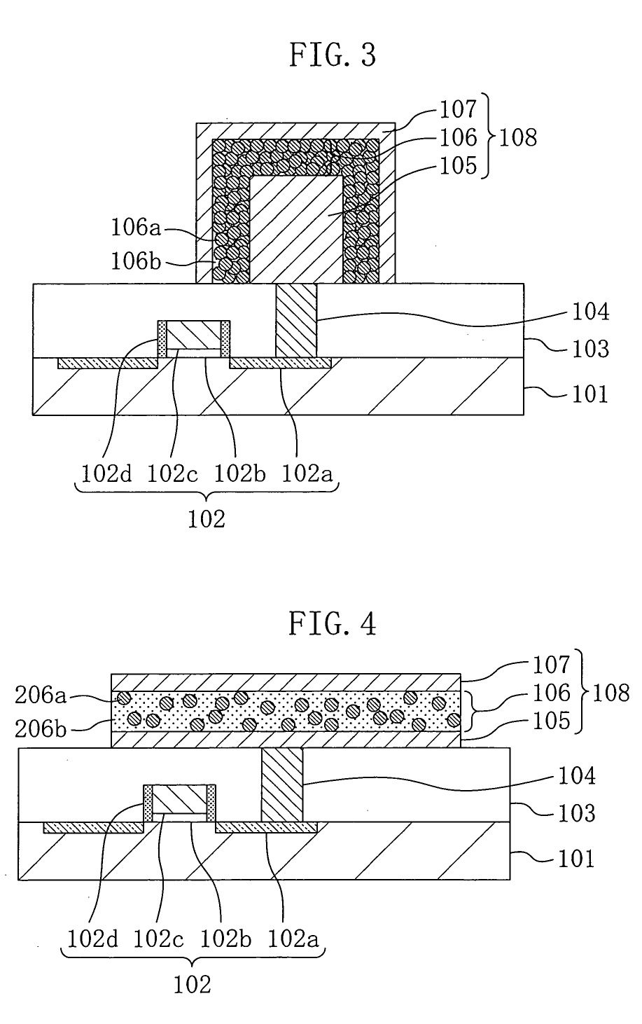

Furthermore, although the manufacturing method of the semiconductor device in which the flat type of capacitor element is formed has been described in the embodiment 1 of the present invention as shown in FIG. 1, the present invention can be implemented even when a capacitor element 108 having a three-dimensional structure is formed by forming a convex lower electrode 105 and then forming the metal oxide thin film 106 and the upper electrode 107 in this order so as to cover the upper and side faces of the lower electrode 105 as shown in FIG. 3 for example. In this case, while a projected area of the capacitor element is kept small, a FeRAM which can store readout electric charges required for the operation can be implemented.

(Embodiment 2)

A semiconductor device according to an embodiment 2 of the present invention will be described with reference to FIG. 4.

FIG. 4 is a sectional view showing an essential part of a structure of the semiconductor device according to the embodiment 2 of the present invention. More specifically, it is a sectional view showing the essential part of the semiconductor device integrating a capacitor element comprising a capacitor insulating film formed of a ferroelectric thin film, and a memory cell transistor. As shown in FIG. 4, the semiconductor device according to the embodiment 2 of the present invention is characterized by a structure of a metal oxide thin film 106 as the capacitor insulating film and other parts are the same as that of the semiconductor device according to the embodiment 1. Thus, a constitution of the metal oxide thin film 106 will be described in detail hereinafter. In addition, in FIG. 4, the same reference numerals are allotted to the same parts as in FIG. 1.

The metal oxide thin film 106 serving as the capacitor insulating film in the embodiment 2 of the present invention comprises a ferroelectric thin film in which a plurality of oxide particles (crystal particles) 206a are diffused in a medium 206b. In addition, the metal oxide which constitutes the oxide particles 206a is SBT like the metal oxide thin film 106. As described in the embodiment 1, it is desirable that a particle diameter of the oxide particle 206a is smaller than a minimum line width of an integrated circuit element comprising a memory transistor 102 formed on a semiconductor substrate 101. Thus, possibility of a short circuit can be considerably reduced even when the oxide particles 206a formed of the metal oxide are attached on the integrated circuit element.

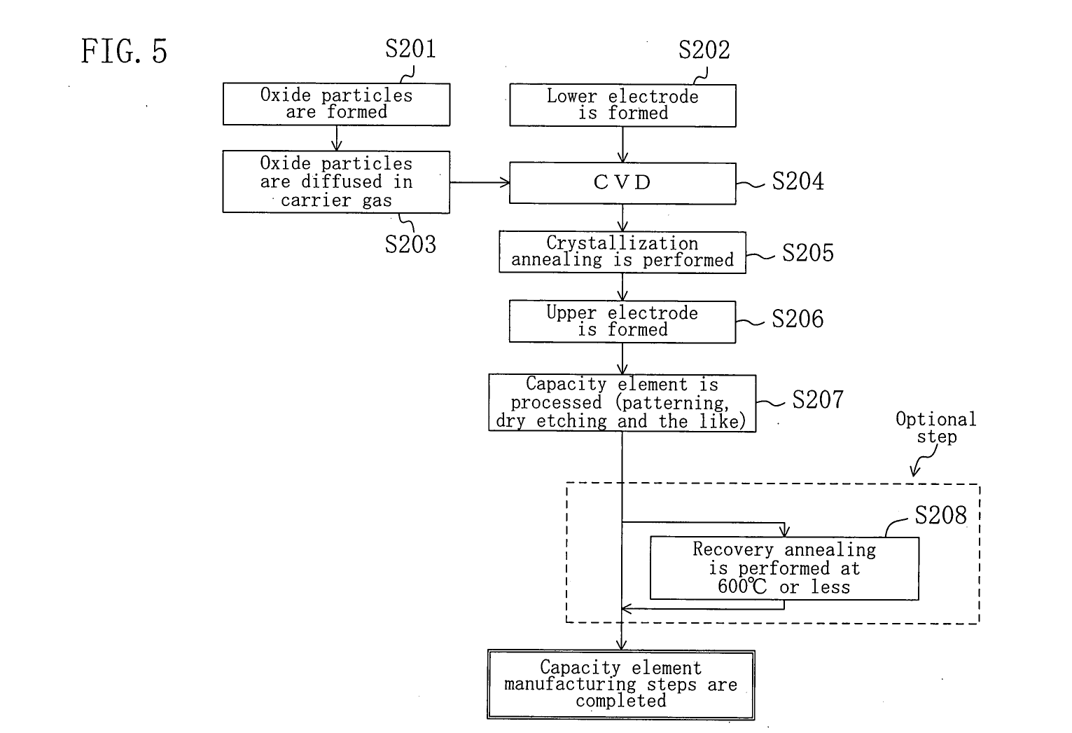

A method of manufacturing the semiconductor device according to the embodiment 2 of the present invention will be described with reference to FIG. 5.

FIG. 5 is a flowchart showing the method of manufacturing the semiconductor device according to the embodiment 2 of the present invention. As shown in FIG. 5, since the manufacturing method of the semiconductor device according to the embodiment 2 of the present invention is characterized by a method of forming the metal oxide thin film 106 serving as the capacitor insulating film, the method of manufacturing a capacitor element 108 including a method of forming the metal oxide thin film 106 will be described in detail. Although a CVD method is used as the method of forming the metal oxide thin film 106 in this description, the spin-on method which will be used in the embodiment 3 or the sputtering method can be used also.

According to this embodiment, when the metal oxide thin film 106 (or its precursor, which will be referred to as the metal oxide thin film 106 simply hereinafter) is formed by the CVD method, it is characterized in that the oxide particles 106a having the same composition as in the metal oxide thin film 106 are diffused in the medium 106b, which will be described in detail with reference to FIG. 5 hereinafter.

First, the oxide particles 206a formed of previously crystallized SBT which constitutes the metal oxide thin film 106 shown in FIG. 4 are formed at step S201 shown in FIG. 5 (a step of manufacturing the oxide particles). In addition, as a method of manufacturing the oxide particles 206a, the previously crystallized oxide particles 206a can be formed by using the same method as described in the embodiment 1.

Meanwhile, a lower electrode 105 shown in FIG. 4 is formed at step S202 shown in FIG. 5 (a step of forming the lower electrode). More specifically, the lower electrode 105 whose lower face is electrically connected to an upper end of a contact plug 104 is formed on an insulation film 103 by the sputtering method. In addition, since a lower end of the contact plug 104 is connected to an impurity diffusion layer 102a, a transistor 102 is electrically connected to the lower electrode 105.

Then, the oxide particles 206a are diffused in carrier gas in order to manufacture the metal oxide thin film 106 formed of the diffused oxide particles 206a in the solvent 206b on the lower electrode 105 at step S203 shown in FIG. 5. More specifically, the oxide particles 206a are diffused in the form of aerosol in the carrier gas which is used to carry an organic raw material used in the CVD method.

Then, the metal oxide thin film 106 formed of the diffused oxide particles 206a in the medium 206b is formed on the lower electrode 105 using the carrier gas in which the oxide particles 206a are diffused in the form of the aerosol by the CVD method at step S204 shown in FIG. 5.

Although the method of diffusing the oxide particles 206a in the carrier gas has been described here, the metal oxide thin film 106 formed of the oxide particles 206a diffused in the medium 206b can be formed by diffusing the oxide particles 206a in oxide gas, or the metal oxide thin film 106 formed of the oxide particles 206a diffused in the solvent 206b can be formed by using other carrier gas for the oxide particles 206a independently of the gas required for the CVD method.

Here, since the metal oxide thin film 106 formed of the oxide particles 206a in the medium 206b formed by the step S204 is normally in an amorphous state, crystallization annealing is performed to crystallize the whole of the metal oxide thin film 106 at step S205 shown in FIG. 5 (a crystallization annealing step). At this time, since the oxide particles 206a are previously crystallized, the oxide particles 206a become seed crystals to promote the crystallization of the metal oxide thin film 106. Therefore, the crystallization can be implemented at a lower temperature in the annealing at the step S205 than a crystallization annealing temperature of the metal oxide thin film 106 formed by the normal CVD method in which the oxide particles 206a are not diffused. In addition, although the crystallization annealing step S205 is performed before an upper electrode forming step which will be described below, in this embodiment, the crystallization annealing step S205 may be performed after the upper electrode forming step S206.

Then, an upper electrode 107 is formed on the metal oxide thin film 106 by the sputtering method at the step S206 shown in FIG. 5 (the upper electrode forming step).

Then, a part other than a region in which the capacitor element 108 in the metal oxide thin film 106 or the upper electrode 107 is to be formed is removed by patterning, dry etching and the like, whereby the capacitor element 108 is formed at step S207 shown in FIG. 5 (a step of processing the capacitor element).

Step S208 (a recovery heat treatment step) shown in FIG. 5 may be performed after the step S207 optionally. That is, since the oxide particles 206a in the metal oxide thin film 106 are sufficiently crystallized, it is not damaged by the process at the step S207. Therefore, even when the recovery heat treatment step at the step S208 is not performed, there can be provided the capacitor element 108 having sufficient characteristics. Therefore, although the recovery heat treatment at the step S208 may be performed according to necessity, when this step is performed, it can be implemented at a low temperature similar to the above embodiment 1.

Thus, the semiconductor device comprising the capacitor element 108 having the metal oxide thin film 106 can be formed on the semiconductor substrate 101.

As described above, according to the semiconductor device and its manufacturing method according to the embodiment 2 of the present invention, since the crystallization annealing for the metal oxide thin film 106 formed of the crystallized oxide particles 206a in the medium 206b can be performed at a low temperature, there can be easily provided the capacitor element 108 which is superior in high dielectric and ferroelectric properties without applying heat damage to the semiconductor substrate 101 or the integrated circuit element such as the transistor 102.

In addition, although the metal oxide thin film 106 is formed by the CVD method in this embodiment, the crystallization annealing temperature can be lowered also even when the spin-on method or the sputtering method is used. In this case, when the spin-on method is used, for example, the crystallization annealing temperature can be lowered also by diffusing the oxide particles 206 in a spin-on raw material previously and then applying its raw material solution by the spin-on method. In addition, when the sputtering method is used, there can be provided the metal oxide thin film 106 formed of the oxide particles 206a diffused in the medium 206b by performing sputtering while gas in the aerosol state in which the oxide particles 206a are diffused is supplied as shown in FIG. 4. In this case also, the crystallization annealing temperature can be lowered.

In addition, although the composition of the oxide particles 206a is the same as that of the metal oxide thin film 106 in this embodiment, a part of constitution metal elements of the oxide particles 206a may be in common with a part of constitution metal elements of the metal oxide thin film 106, or the composition of the oxide particles 206a may be completely different from that of the metal oxide thin film 106. For example, the crystallization annealing temperature can be considerably lowered when the metal oxide thin film 106 is formed of PZT and the oxide particles 206a is formed of PbTiO₃ which is an oxide of a metal element constituting PZT.

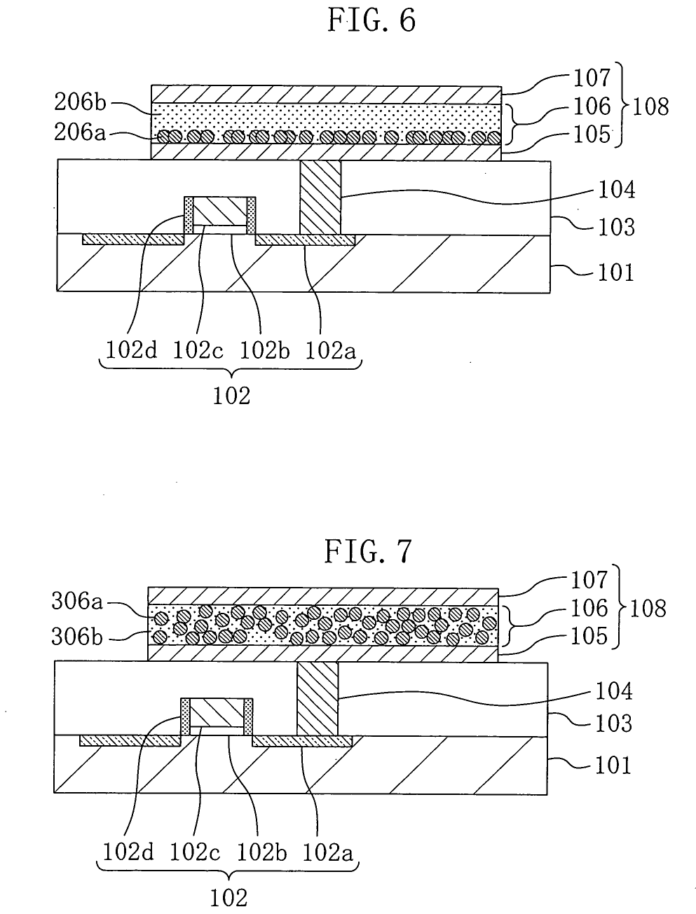

Furthermore, instead of diffusing the oxide particles 206a in the metal oxide thin film 106 as shown in FIG. 4, by integrating the oxide particles 206a on the lower electrode 105 previously as shown in FIG. 6, there can be provided the metal oxide thin film 106 having a structure in which the oxide particles 206a are arranged at a lower part in the medium 206b.

Furthermore, similar to the embodiment 1, instead of forming the capacitor element having the flat structure, even when a capacitor element 108 having a three-dimensional structure such as concave type or a convex type is formed, the present invention can be implemented also. In this case, while a projected area of the capacitor element is kept small, a FeRAM which can store readout electric charges required for the operation can be implemented.

(Embodiment 3)

A semiconductor device according to an embodiment 3 of the present invention will be described with reference to FIG. 7.

FIG. 7 is a sectional view showing an essential part of a structure of the semiconductor device according to the embodiment 3 of the present invention. More specifically, it is a sectional view showing the essential part of the semiconductor device integrating a capacitor element comprising a capacitor insulating film formed of a ferroelectric thin film, and a memory cell transistor. As shown in FIG. 7, the semiconductor device according to the embodiment 3 of the present invention is characterized by a structure of a metal oxide thin film 106 as a capacitor insulating film and other parts are the same as that of the semiconductor device according to the embodiment 1. Thus, a constitution of the metal oxide thin film 106 will be described in detail hereinafter. In addition, in FIG. 7, the same reference numerals are allotted to the same parts as in FIG. 1.

The metal oxide thin film 106 serving as the capacitor insulating film according to the embodiment 3 of the present invention comprises the ferroelectric thin film in which oxide particles (crystal particles) 306a formed of a plurality of metal oxides are diffused in a medium material 306b. The metal oxide constituting the oxide particles 306a is SBT and the medium material 306b is SrTa₂O₆ (referred to as ST hereinafter). When the metal oxide thin film 106 has the above constitution, since the oxide particle 106a and the medium material 106b have two kinds of common metal elements, diffusion of the metal element can be prevented between the oxide particle 306a and the medium material 306b. Therefore, composition is prevented from being changed in each of the oxide particle 306a and the medium material 306b. Therefore, the ferroelectric property of the oxide particle 306a can be prevented from deteriorating. In addition, although there are two kinds of metal elements which are common in the oxide particle 306a and the medium material 306b in the this embodiment, even when the number of the common metal elements is three or more of course, and it is one depending on the kind of the metal element constituting each of them, the same effect can be provided.

Still furthermore, it is desirable that a particle diameter of the oxide particle 306a is formed so as to be smaller than a minimum line width of an integrated circuit element comprising a memory transistor 102 formed on a semiconductor substrate 101 similar to the above embodiments. Thus, even when the oxide particles 306a formed of the metal oxide are attached on the integrated circuit element, possibility causing a short circuit can be considerably reduced. In addition, according to this embodiment, the particle diameter of the oxide particle 306a is formed so as to be about 30 nm or less which is considerably small as compared with the minimum line width 130 nm of the integrated circuit element (its forming method will be described in detail below).

As described above, according to the semiconductor device of this embodiment of the present invention, the ferroelectric thin film serving as the metal oxide thin film 106 comprises the oxide particles 306a and the medium material 306b, in which the oxide particles 306a formed of the plurality of metal oxides are diffused in the medium material 306b. In this constitution, since the oxide particles 306a provide a ferroelectric property, it is not always necessary that the medium material 306b has been crystallized. The metal oxide thin film 106 according to this embodiment can provide the ferroelectric property required as the capacitor insulating film constituting the capacitor element 108. In addition, since it is not necessary to further perform high-temperature annealing for the metal oxide thin film 106 serving as the capacitor insulating film, when the oxide particles 306a formed of the metal oxide are previously prepared, the metal oxide thin film 106 can be formed at a low temperature on the semiconductor substrate 101 on which the integrated circuit elements such as the memory cell transistor 102 are form ed so that the heat damage is not applied to the integrated circuit element such as the memory cell transistor 102.

In addition, since the medium material 306b has a relative dielectric constant higher than that of silicon oxide, there can be provided the metal oxide thin film 106 serving as the ferroelectric thin film having a high relative dielectric constant.

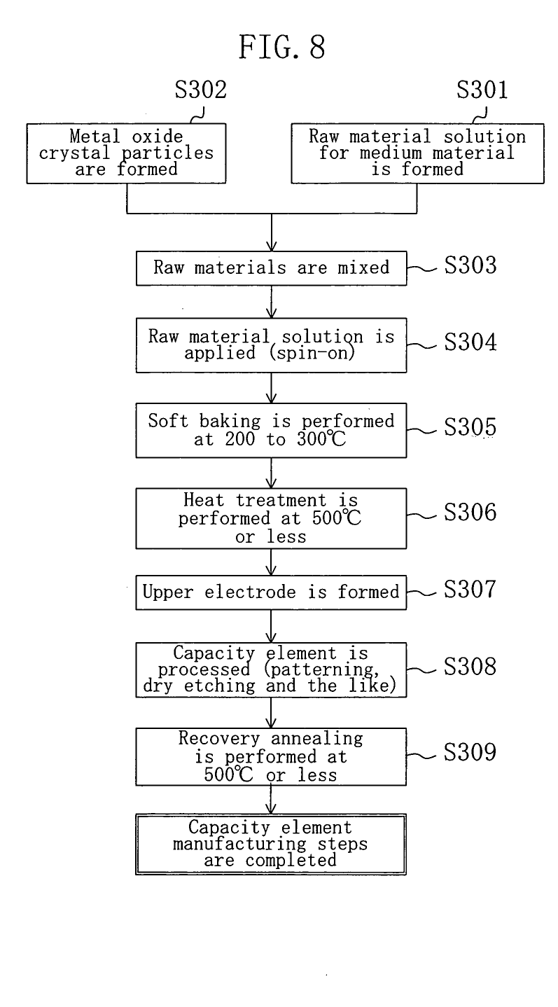

A method of manufacturing the semiconductor device according to the embodiment 3 of the present invention will be described with reference to FIG. 8.

FIG. 8 is a flowchart showing the method of manufacturing the semiconductor device according to the embodiment 3 of the present invention. As shown in FIG. 8, since the manufacturing method of the semiconductor device according to the embodiment 3 of the present invention is characterized by a method of forming the metal oxide thin film 106 serving as the capacitor insulating film, the method of manufacturing the capacitor element 108 including the method of forming the metal oxide thin film 106 will be described in detail hereinafter.

First, a raw material solution for the medium material is formed at step S301 shown in FIG. 8. That is, a spin-on raw material solution containing ST which is the medium material 306b is prepared (a step of forming the raw material solution for the medium material). Then, crystal particles formed of SBT (referred to as the SBT crystal particles hereinafter) which are oxide particles 306a formed of the metal oxide are formed (a step of forming the metal oxide crystal particles).

Here, a method of manufacturing the SBT crystal particles whose diameter is 30 nm or less will be described.

As a method of manufacturing particles of nanosize such as the SBT crystal particles whose diameter is 30 nm or less, there are a grinding method, a gas phase method using an electric furnace, chemical flame, a plasma laser and the like, a liquid phase method in a chemical manner such as coprecipitation, chemical deposition, alcoxide, hydrothermal synthesis and the like, and a liquid phase method in a physical manner such as freeze drying, spray drying, evaporative decomposition and the like (refer to “The Latest Information of Manufacturing, Evaluation, Application and Device of Nanoparticle” edited by Koizumi, Okuyama, and Sakka, published from CMC Publishing Co., Ltd. October, 2002 for example). Since it is preferable that a particle having a preferable crystal property can be manufactured to form a nucleus in crystal growth from the particle of nanosize in the following step, the plasma method is used in this embodiment. In this case, organic raw material liquid of SBT is sprayed in oxygen plasma and sintered at a high temperature of 1200° C. or more in a moment. Thus, since the particles can be manufactured at the high temperature, this method is suitable for providing particles having a layered perovskite crystal structure having a ferroelectric property, and large amount of processes can be performed in this method. When the crystal property of the SBT crystal particle manufactured by the plasma method was examined by X-ray analysis method, only a peak regarding an index peculiar to the layered perovskite crystal structure was detected. Furthermore, when the SBT crystal particle was observed by a transmission electron microscope (TEM), it was confirmed that the SBT crystal particle was a single crystal. Therefore, the SBT crystal particle manufactured by the plasma method is a single crystal having the layered pevroskite crystal structure. In addition, since the SBT crystal particles manufactured by the plasma method are fused by hitting each other in the plasma and becomes large particles, the target SBT crystal particles whose diameter is 30 nm or less and the SBT crystal particles whose diameter is more than 30 nm are mixed in a SBT crystal particle group. When the particle diameter of the particle in the group was examined, the particle diameter was ranged from 25 nm to 300 nm.

Thus, the SBT crystal particle group is suspended in pure water and classified through setting.

In general, setting velocity u of particles due to gravity is expressed by the following equation (1).
U=D²(ρ−ρ₀)g/18η (1)
(where D is a particle diameter, ρ is a density of particles, ρ₀ is a density of a solvent, η is a viscosity of the solvent, and g is gravity acceleration)

When the setting velocity u of the particle is calculated with the equation (1), the setting velocities of the particles having diameters 100 nm and 30 nm in the liquid are about 0.04 mm/h and 0.0036 mm/h, respectively. Thus, when the liquid is put in a container having a height of 50 mm and left for three months, for example, the particle having the diameter of 100 nm is set while the particle having the diameter of 30 nm is floating in the liquid. Therefore, only the SBT crystal particles having the diameter of 30 nm or less can be skimmed from the container. Thus, the SBT crystal particles having the diameter of 30 nm or less to be the oxide particles 306a can be provided. In addition, although the description has been made using the setting method here, the crystal particles can be classified in a short time by using a centrifugal separator or a differential type of electrostatic classifier.

Furthermore, as the method forming the SBT crystal particles, the present invention is not limited to the above method. For example, the SBT crystal particles can be manufactured such that the target SBT is irradiated with a laser by a laser ablation method, particles generated at that time are heated in a furnace and then collected to manufacture the SBT crystal particles.

Then, the SBT crystal particles are diffused in the spin-on raw material solution containing ST at step S303 shown in FIG. 8 (a raw material mixing step).

Then, the spin-on raw material solution in which the SBT crystal particles are diffused is applied to the semiconductor substrate 101 by the normal spin-on method at step S304 shown in FIG. 8 (a raw material solution applying (spin-on) step). In addition, as shown in FIG. 7 in the above, the memory cell transistor 102, a contact plug 104 and a patterned lower electrode 105 are previously formed on the semiconductor substrate 101.

Then, a precursor thin film of the metal oxide thin film 106 serving as the capacitor insulating film which is the ferroelectric thin film is formed by heating the semiconductor substrate 101 at 200 to 300° C. at step S305 shown in FIG. 8 (a soft baking step). At this time, a ratio of the oxide particles 206a (SBT crystal particles) in the precursor thin film is desirably smaller than a ratio of the medium material 306b (ST) in the precursor thin film. In addition, by increasing the ratio of the oxide particles 306a (SBT crystal particles) in the precursor thin film, there can be provided a metal oxide thin film in which oxide particles 306a are fused to each other by a fusion material like an embodiment 4 which will be described below.

Then, an organic material contained in the precursor thin film is decomposed and oxidized by heating the precursor thin film formed at the step S304 at 500° C. or less at step S306 shown in FIG. 8 (a heat treatment step). Thus, there is provided the metal oxide thin film 106 formed of the ferroelectric thin film in which the oxide particles 306a (SBT crystal particles) formed of the plurality of metal oxides are diffused in the medium material 306b (ST). At this time, since the oxide particles 306a are already crystallized, it is not always necessary to crystallize the medium material 306b. Therefore, the heat treatment temperature at the step S306 can be lowered as compared with the heat treatment temperature when the ferroelectric thin film is formed by the normal spin-on method as in the conventional example. For example, the metal oxide thin film 106 formed of the ferroelectric thin film which provides the sufficient ferroelectric property can be formed at the heat treatment temperature of 300 to 500° C. which is lower than the conventional example.

Then, an upper electrode 107 is formed on the metal oxide thin film 106 at step S307 shown in FIG. 8 (an upper electrode forming step).

Then, a part other than the region in which the capacitor element 108 is to be formed of the metal oxide thin film 106 and the upper electrode 107 is removed by patterning and dry etching and the like at step S308 shown in FIG. 8 (a step of processing the capacitor element).

Then, at step S309 shown in FIG. 8, the semiconductor substrate is heated at 500° C. or less to remove processing damage generated in the metal oxide thin film 106 at the step 308 (a recovery heat treatment step). The heat treatment temperature at this step S309 can be lowered similar to the heat treatment temperature at the step S306.

Thus, the semiconductor device having the capacitor element 108 on the semiconductor substrate 101 can be formed.

As described above, according to the manufacturing method of the semiconductor device according to the embodiment 3 of the present invention, since the heat treatment temperature at the step S306 (the heat treatment step) and the step S309 (recovery heat treatment step) can be lowered, there can be easily provided the capacitor element 108 comprising the metal oxide thin film 106 formed of the ferroelectric thin film having the superior ferroelectric property and the like without applying heat damage to the semiconductor substrate 101 and the integrated circuit element such as the memory cell transistor 102 formed thereon. Furthermore, since the normal spin-on method can be used, the metal oxide thin film 106 formed of the ferroelectric thin film can be easily formed.

In addition, although the crystal particles formed of SBT are used as the oxide particles 306a and ST is used as the medium material 306b in this embodiment, crystal particles formed of another ferroelectric material such as PZT (Pb (Zr, Ti) O₃)) or BLT ((Bi, La)₄Ti₃O₁₂) may be used as the oxide particles 306a, and another oxide such as a lead oxide may be used as the medium material 306b. When the crystal particles formed of PZT are used as the oxide particles 306b and the lead oxide is used as the medium material 306b, since Pb is the common metal element for them, metal elements are prevented from being diffused between the oxide particles 306a formed of PZT and the medium material 306b formed of the lead oxide. As a result, compositions in them can be prevented from changing so that the ferroelectric property of the oxide particle 306a can be prevented from deteriorating.

In addition, although a description has been made of the case where the oxide particles 306a (SBT crystal particles) and the medium material 306b (ST) have the two common metal elements (Sr and Ta) in this embodiment, the common metal element may not exist depending on the material constituting the oxide particles 306a and the medium material 306b. For example, in a case where an amorphous material such as a glass oxide is used as the medium material 306b, the heat treatment temperature at the step S306 (the heat treatment step) can be considerably lowered. Especially, glass borate which is a low melting point glass having a low glass transition point temperature and the like may be preferably used.

In addition, the present invention is not limited to the case where the medium material 306b comprises the oxide and an organic material having a high dielectric constant such as polypropylene may be used, for example. In this case, the step S306 (the heat treatment step) may be omitted, so that a thermal budget which is needed to form the metal oxide thin film 106 formed of the ferroelectric thin film can be considerably reduced.

Furthermore, although the description has been made of the case where the spin-on method is used as the method of forming the metal oxide thin film 106 formed of the ferroelectric thin film in this embodiment, the chemical vapor deposition method or the sputtering method may be used.

In addition, the ferroelectric thin film and its forming method have been described in this embodiment, the present invention can be applied to a high dielectric thin film and its forming method. In this case, crystal particles formed of a high dielectric material may be used as the oxide particles 306a. For example, BST (Sr, Bi) TiO₃) or Ta₂O₅ may be used.

Furthermore, similar to the embodiment 1, instead of forming the capacitor element having the flat structure, even when a capacitor element 108 having a three-dimensional structure such as a concave type or a convex type is formed, the present invention can be implemented also. In this case, while a projected area of the capacitor element is kept small, a FeRAM which can store readout electric charges required for the operation can be implemented.

(Embodiment 4)

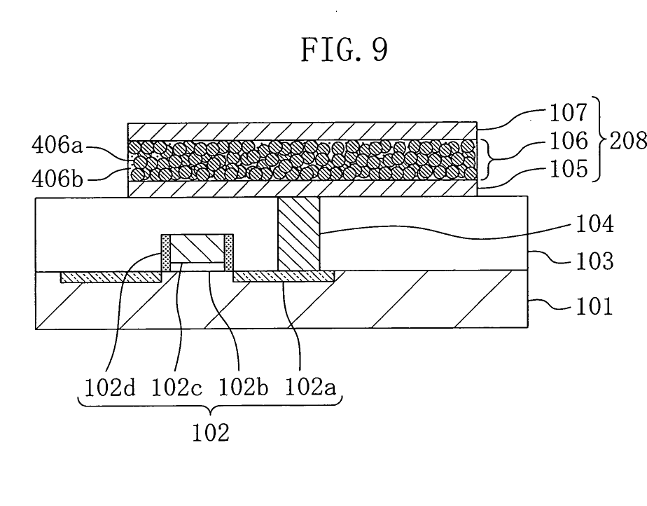

A semiconductor device according to an embodiment 4 of the present invention will be described with reference to FIG. 9.

FIG. 9 is a sectional view showing an essential part of a structure of the semiconductor device according to the embodiment 4 of the present invention. More specifically, it is a sectional view showing the essential part of the semiconductor device integrating a capacitor element comprising a capacitor insulating film formed of a ferroelectric thin film, and a memory cell transistor. As shown in FIG. 9, the semiconductor device according to the embodiment 4 of the present invention is characterized by a structure of a metal oxide thin film 106 as the capacitor insulating film and other parts are the same as that of the semiconductor device according to the embodiment 1. Thus, a constitution of the metal oxide thin film 106 will be described in detail hereinafter. In addition, in FIG. 9, the same reference numerals are allotted to the same parts as in FIG. 1.

The metal oxide thin film 106 as the capacitor insulating film according to the embodiment 4 of the present invention is a ferroelectric thin film in which oxide particles 406a formed of a plurality of metal oxides are fused (bonded) to each other by a fusion material 406b (bonding material). In addition, the metal oxide constituting the oxide particles 406a is PZT, and the fusion material 406b is an amorphous oxide glass (referred to as the glass simply). In this embodiment, a lead glass containing 40% by weight of lead is used. Thus, since the oxide particles 406a and the medium material 406b comprise the common metal element Pb, the metal element is prevented from being diffused between the oxide particles 306a formed of PZT and the medium material 306b formed of the lead oxide. As a result, compositions in them can be prevented from changing and the ferroelectric property of the oxide particle 306a can be prevented from deteriorating.

In addition, similar to the above embodiments, it is desirable that a particle diameter of the oxide particle 406a is formed so as to be smaller than a minimum line width of an integrated circuit element comprising a memory transistor 102 formed on a semiconductor substrate 101. According to this embodiment, the oxide particle 406a is so constituted that its particle diameter becomes about 30 nm or less which is considerably smaller as compared with the minimum line width 130 nm of the integrated circuit element by the method as described in the embodiment 3.

As described above, the semiconductor device according to the embodiment 4 of the present invention is constituted such that the oxide particles 406a formed of the plurality of metal oxides are fused to each other by the fusion material. In this constitution, since the oxide particles 406a provide a ferroelectric property, it is not always necessary that the fusion material 406b has been crystallized. The ferroelectric thin film according to this embodiment can provide the ferroelectric property required as the metal oxide thin film 106 constituting the capacitor element 108. In addition, since the fusion material 406b is provided only to fuse the oxide particles 406a formed of the plurality of metal oxides, its ratio in the ferroelectric thin film can be extremely small. Therefore, there can be provided the ferroelectric property which is extremely close to that of the ferroelectric thin film containing only the metal oxide constituting the oxide particles 406a. In addition, since it is not necessary to further perform high-temperature annealing for the metal oxide thin film 106 formed of the ferroelectric thin film, when the oxide particles 406a formed of the metal oxides are previously prepared, the ferroelectric thin film can be formed at a low temperature on the semiconductor substrate 101 on which the integrated circuit elements such as the memory cell transistor 102 are formed so that the heat damage is not applied to the integrated circuit element such as the memory cell transistor 102.

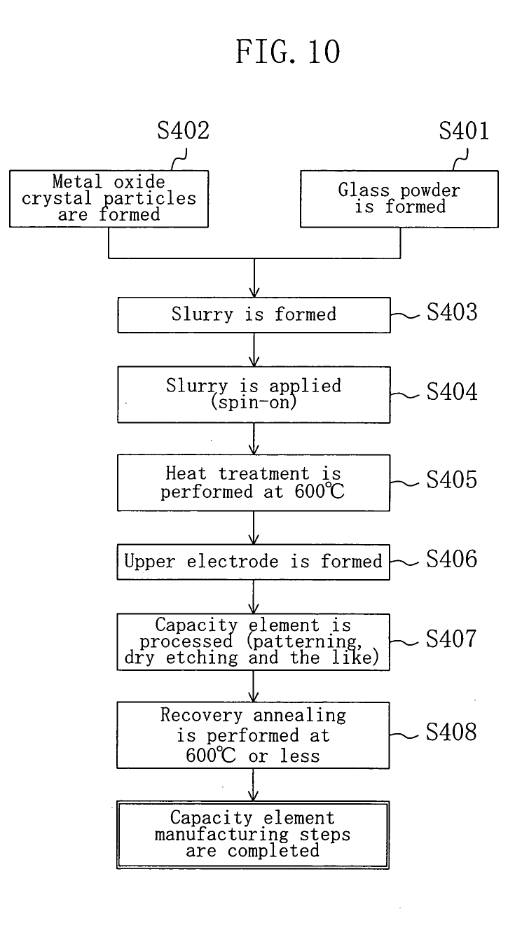

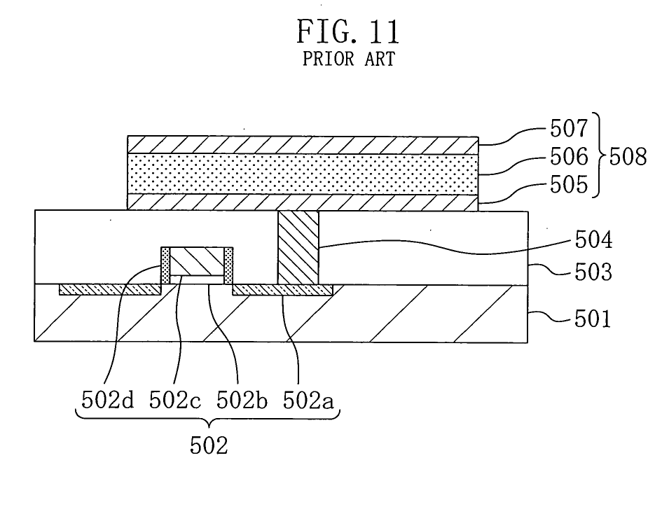

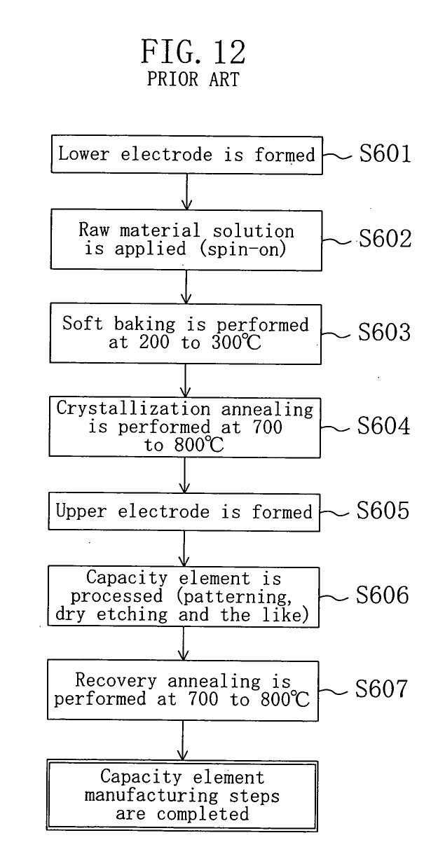

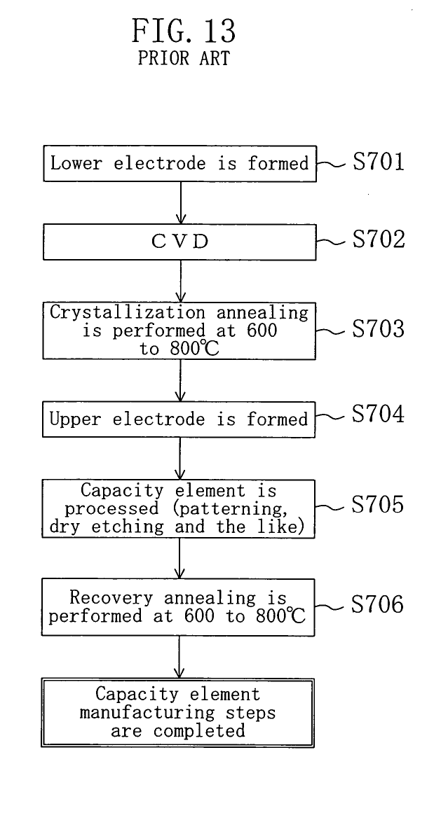

A method of manufacturing the semiconductor device according to the embodiment 4 of the present invention will be described with reference to FIG. 10.

FIG. 10 is a flowchart showing the method of manufacturing the semiconductor device according to the embodiment 4 of the present invention. As shown in FIG. 10, since the manufacturing method of the semiconductor device according to the embodiment 4 of the present invention is characterized by a method of forming the metal oxide thin film 106 serving as the capacitor insulating film, a method of manufacturing the capacitor element 108 including the method of forming the metal oxide thin film 106 will be described in detail hereinafter.

A bulk lead glass containing 40% by weight of lead is ground to form glass powder to provide the fusion material 406b at step S401 (a glass powder forming step). Then, crystal particles formed of PZT (referred to as the PZT crystal particles hereinafter) to become the oxide particles 406a formed of the metal oxide are formed by the same method as described in the embodiment 1 (a step of forming the metal oxide crystal particles).

Then, the PZT crystal particles and the glass powder are mixed in a solution in which polyvinyl alcohol is dissolved in water to form a mixture slurry of the metal oxide (referred to as the slurry simply) at step S403 (a slurry forming step). At this time, it is desirable that a ratio of the PZT crystal particles in the slurry is higher than that of the glass powder in the slurry. In this embodiment, a mixture ratio of the glass powder and the PZT crystal particles is 1:9 by volume.

The ferroelectric thin film in which the oxide particles 406a are diffused in the lead glass (medium material) can be formed like in the embodiment 3 by adjusting the mixture ratio of the glass powder and the PZT crystal particles.

Then, the slurry is applied to the semiconductor substrate 101 by the normal spin-on method at step S404 (a slurry applying (spin-on) step). In addition, as shown in FIG. 9 in the above, the memory cell transistor 102, a contact plug 104 and a patterning lower electrode 105 and the like are previously formed on the semiconductor substrate 101.

Then, the glass powder is softened to fuse the PZT crystal particles to each other by heating up to 600° C. which is a glass softening point of the lead glass at step S405 (a heat treatment step). Thus, there is formed the metal oxide thin film 106 formed of the ferroelectric thin film in which the oxide particles 406a (PZT crystal particles) formed of the plurality of metal oxides are fused by the fusion material 406b (lead glass). At this time, since the oxide particles 406b are previously crystallized, it is not always necessary for the fusion material 406b to be crystallized. Therefore, the heat treatment temperature at the step S405 (heat treatment step) can be lowered as compared with the heat treatment temperature when the ferroelectric thin film is formed by the normal spin-on method like in the conventional example. Thus, there can be formed the metal oxide thin film 106 formed of the ferroelectric thin film which provides the enough ferroelectric property at the heat treatment temperature of 600° C., for example which is relatively low for the heat treatment temperature.

In addition, polyvinyl alcohol serving as a binder used in forming the slurry can be removed by heat decomposition by performing the step S405 (heat treatment step) in an oxygen atmosphere.

Then, similar to the embodiment 1, the semiconductor device having the capacitor element 108 is formed on the semiconductor substrate 101 through step S406 (an upper electrode forming step), step S407 (a capacitor element processing step) and step S408 (a recovery heat treatment step). In addition, in the step S408 (the recovery heat treatment step), processing damage generated in the metal oxide thin film 106 at the step S407 (the capacitor element processing step) can be removed by heating the semiconductor substrate 101 at about 600° C.

As described above, according to the manufacturing method of the semiconductor device of the embodiment 4 of the present invention, since the metal oxide thin film 106 formed of the ferroelectric thin film can be formed at the heat treatment temperature 600° C. or less at the step S405 (the heat treatment step), there can be easily provided the capacitor element 108 comprising the metal oxide thin film 106 formed of the ferroelectric thin film having the excellent ferroelectric property and the like without applying heat damage to the semiconductor substrate 101 and the integrated circuit element such as the memory cell transistor 102 formed thereon. Furthermore, since the normal spin-on method can be used, the ferroelectric thin film can be easily formed.

In addition, although the description has been made of the case where the crystal particles formed of PZT are used as the oxide particles 406a formed of the metal oxide in this embodiment, crystal particles formed of another ferroelectric material such as SBT or BLT may be used as the oxide particles 406a.

Furthermore, although the description has been made of the case where the lead glass is used as the fusion material 406b in this embodiment, glass containing glass borate or germanium may be used as the fusion material 406b. In addition, an organic material having a high dielectric constant such as epoxy resin or polypropylene may be used as the fusion material 406b. In this case, the step S405 (the heat treatment step) may be omitted, so that a thermal budget which is needed to form the metal oxide thin film 106 formed of the ferroelectric thin film can be considerably reduced.

Furthermore, although the ferroelectric thin film and its forming method has been described in this embodiment, the present invention can be applied to a high dielectric thin film and its forming method also. In this case, crystal particles formed of a high dielectric material may be used as the oxide particles 406a. For example, BST (Sr, Bi)TiO₃) or Ta₂O₅ may be used.

Furthermore, similar to the embodiment 1, instead of forming the capacitor element having the flat structure, even when a capacitor element 108 having a three-dimensional structure such as a concave type or a convex type is formed, the present invention can be implemented also. In this case, while a projected area of the capacitor element is kept small, a FeRAM which can store readout electric charges required for the operation can be implemented.

In addition, the present invention can be effectively applied to the semiconductor device in which the capacitor element having the metal oxide thin film is formed on the semiconductor substrate on which the semiconductor element such as the transistor is formed, and its manufacturing method.

1. A semiconductor device in which a thin film containing a metal oxide is formed on a semiconductor element, wherein
the thin film is an aggregate of crystal particles formed of the metal oxide, and
the crystal particles are bonded to each other at a part of its surface.

2. The semiconductor device according to claim 1, wherein an average particle diameter of the crystal particle is smaller than a minimum line width of the semiconductor element.

3. The semiconductor device according to claim 1, wherein the thin film comprises a ferroelectric thin film or a high dielectric thin film.

4. A semiconductor device in which a thin film containing a metal oxide is formed on a semiconductor element, wherein
the thin film comprises crystal particles formed of the metal oxide and diffused in a medium material.

5. The semiconductor device according to claim 4, wherein the medium material is an amorphous material.

6. The semiconductor device according to claim 4, wherein the medium material is formed of an organic material.

7. The semiconductor device according to claim 4, wherein the medium material has a relative dielectric constant higher than that of a silicon oxide.

8. The semiconductor device according to claim 4, wherein an average particle diameter of the crystal particle is smaller than a minimum line width of the semiconductor element.

9. The semiconductor device according to claim 4, wherein the thin film comprises a ferroelectric thin film or a high dielectric thin film.

10. A semiconductor device in which a thin film containing a metal oxide is formed on a semiconductor element, wherein
the thin film comprises crystal particles formed of the metal oxide and bonded by a bonding material.

11. The semiconductor device according to claim 10, wherein the bonding material is an amorphous material.

12. The semiconductor device according to claim 10, wherein the bonding material is formed of an organic material.

13. The semiconductor device according to claim 10, wherein the bonding material has a relative dielectric constant higher than that of a silicon oxide.

14. The semiconductor device according to claim 10, wherein an average particle diameter of the crystal particle is smaller than a minimum line width of the semiconductor element.

15. The semiconductor device according to claim 10, wherein the thin film comprises a ferroelectric thin film or a high dielectric thin film.

16. A method of manufacturing a semiconductor device comprising:
a step of depositing crystal particles formed of a metal oxide, on a substrate, and
a step of forming a thin film formed of the bonded crystal particles, on the substrate by performing a heat treatment for the substrate.

17. A method of manufacturing a semiconductor device comprising:
a step of diffusing crystal particles formed of a metal oxide, in a raw material solution containing a medium material;
a step of applying the raw material solution containing the diffused crystal particles, onto a substrate; and
a step of forming a thin film formed of the diffused crystal particles in the medium material, on the substrate by performing a heat treatment for the substrate.

18. A method of manufacturing a semiconductor device comprising:
a step of diffusing crystal particles formed of a metal oxide, in raw material gas used in a chemical vapor deposition method or raw material gas carrying gas; and
a step of forming a thin film formed of the diffused crystal particles in the medium material, on the substrate using the raw material gas or raw material gas carrying gas in which the crystal particles are diffused, by a chemical vapor deposition method.

19. A method of manufacturing a semiconductor device comprising:
a step of diffusing crystal particles formed of a metal oxide in a raw material solution containing a bonding material;
a step of applying the raw material solution containing the diffused crystal particles, onto a substrate; and
a step of forming a thin film formed of the crystal particles bonded by the bonding material, on the substrate by performing a heat treatment for the substrate.

20. A method of manufacturing a semiconductor device comprising:
a step of manufacturing a mixture solution in which crystal particles formed of a metal oxide and particles formed of a medium material are mixed in a solvent;
a step of applying the mixture solution onto a substrate; and
a step of forming a thin film formed of the crystal particles diffused in the medium material, on the substrate by softening the crystal particles formed of the medium material, by performing a heat treatment for the substrate.

21. A method of manufacturing a semiconductor device comprising:
a step of manufacturing a mixture solution in which crystal particles formed of a metal oxide and particles formed of a bonding material are mixed in a solvent;
a step of applying the mixture solution onto a substrate; and
a step of forming a thin film formed of the crystal particles bonded by the bonding material, on the substrate by softening the crystal particles formed of the bonding material, by performing a heat treatment for the substrate.
